(19) United States
(12) Patent Application Publication
(10) Pub. No.: US 2026/0293385 A1
(43) Pub. Date: Sep. 24, 2026

(54) LIGHT-EMITTING DEVICE

(71) Applicant: LITE-ON TECHNOLOGY CORPORATION, Taipei (TW)

(72) Inventors: Hong-Ye LAI, Taipei (TW); Kai-Chieh LIANG, Taipei (TW); Sheng-Yun WANG, Taipei (TW); Wei-Le SU, Taipei (TW)

(21) Appl. No.: 19/572,917

(22) Filed: Mar. 20, 2026

Related U.S. Application Data
(60) Provisional application No. 63/776,281, filed on Mar. 24, 2025.

(30) Foreign Application Priority Data
Aug. 29, 2025 (CN) 202521852284.7

(51) Int. Cl. H10H 20/856; H10H 20/853

(52) U.S. Cl. CPC H10H 20/856; H10H 20/853

(57) ABSTRACT

A light-emitting device includes a substrate, a semiconductor element, at least one light-emitting element, a reflective cover, a first barrier wall and at least one bonding wire. The substrate has a first surface, and the first surface has a first chip bonding area and a second chip bonding area. The semiconductor chip is disposed on the first chip bonding area. The light-emitting element is disposed in the second chip bonding area. The reflective cover covers the semiconductor chip. The first barrier wall is disposed between the semiconductor element and the light-emitting element. The bonding wire is electrically connected to the semiconductor element and the light emitting element. The height of the reflective cover is greater than the height of the first barrier wall, and the height of the first barrier wall is greater than the height of the light-emitting element.

This application claims the benefit of U.S. Provisional Application Ser. No. 63/776,281, filed Mar. 24, 2025 and China application Serial No. 202521852284.7, filed Aug. 29, 2025, the subject matters of which are incorporated herein by reference.

### BACKGROUND OF THE INVENTION

### Field of the Invention

The invention relates in general to a semiconductor device, and more particularly to a light emitting device.

### Description of the Related Art

With the recent development of light-emitting diodes (LEDs), packages combining driver integrated circuits (ICs) with LEDs have been developed. However, the driver IC absorbs light from the LEDs, resulting in high light extraction efficiency issues with existing designs. Therefore, the industry urgently needs a new type of package design to improve this problem.

### SUMMARY OF THE INVENTION

The invention is directed to a light-emitting device for improving light extraction efficiency.

According to one aspect of the present invention, a light-emitting device is provided, including a substrate, a semiconductor element, at least one light-emitting element, a reflective cover, a first barrier wall, and at least one bonding wire. The substrate has a first surface having a first chip bonding area and a second chip bonding area. The semiconductor element is disposed in the first chip bonding area. The light-emitting element is disposed in the second chip bonding area. The reflective cover covers the semiconductor element. The first barrier wall is disposed between the semiconductor element and the light-emitting element. The bonding wire electrically connects the semiconductor element and the light-emitting element. The height of the reflective cover is greater than the height of the first barrier wall, and the height of the first barrier wall is greater than the height of the light-emitting element.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a perspective view of a light-emitting device according to an embodiment of the present invention.

FIG. 2 is a schematic cross-sectional view of a light-emitting device according to an embodiment of the present invention.

FIG. 3 is a perspective view of a light-emitting device according to another embodiment of the present invention.

FIG. 4 is a plan view of a light-emitting device according to another embodiment of the present invention.

FIG. 5 is a schematic cross-sectional view of a light-emitting device according to another embodiment of the present invention.

FIG. 6 is a schematic diagram of a light-emitting device according to another embodiment of the present invention.

FIG. 7 is a schematic diagram of a light-emitting device according to a comparative example.

FIGS. 8A to 8J are schematic cross-sectional views of a method for manufacturing a light-emitting device according to an embodiment of the present invention.

### DETAILED DESCRIPTION OF THE INVENTION

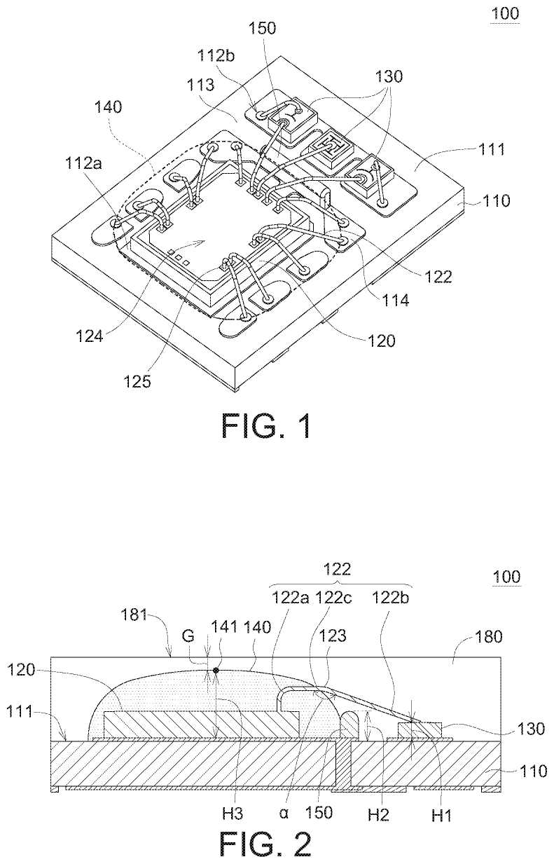

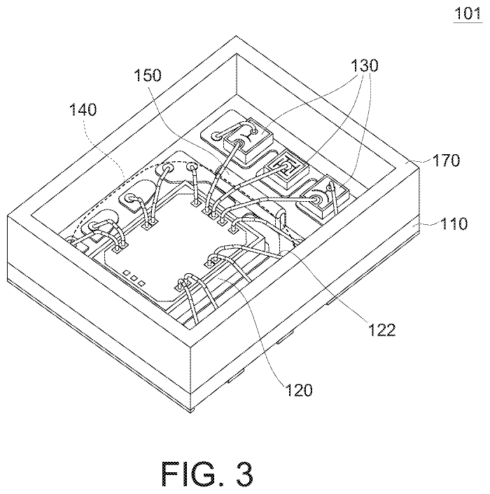

Referring to FIGS. 1 and 2, FIG. 1 is a perspective view of a light-emitting device 100 according to an embodiment of the present invention, and FIG. 2 is a schematic cross-sectional view of the light-emitting device 100 according to an embodiment of the present invention. The light-emitting device 100 includes a substrate 110, a semiconductor element 120, bonding wires 122, at least one light-emitting element 130, a reflective cover 140, and a first barrier wall 150. To illustrate the semiconductor element 120 covered by the reflective cover 140, FIG. 1 is a perspective view with the reflective cover 140 outlined in dashed lines. FIG. 1 does not depict the transmissive encapsulant 180 shown in FIG. 2. Although FIG. 1 depicts only a single light-emitting device 100, it is conceivable that multiple semiconductor elements 120 can be formed on the same substrate panel and, after packaging, singulated to form separate light-emitting devices 100.

As shown in FIG. 1, the semiconductor element 120 is disposed on a first chip bonding area 112a on a first surface 111 of a substrate 110, and the light-emitting element 130 is disposed on a second chip bonding area 112b on the first surface 111 of the substrate 110. The first chip bonding area 112a and the second chip bonding area 112b are separated by an isolation region 113. The first barrier wall 150 is disposed on the isolation region 113.

Furthermore, the semiconductor element 120 and the light-emitting element 130 can be attached to the first chip bonding area 112a and the second chip bonding area 112b respectively using an adhesive (not shown). The semiconductor element 120 can be a logic control chip, a transistor, or a switch element, and the light-emitting element 130 can be a light-emitting diode (LED), which is a type of electroluminescent semiconductor light-emitting element in which electrons and holes combine to release energy in the form of photons. The light-emitting element 130 can be disposed on the substrate 110 through a die-bonding process and electrically connected to the semiconductor element 120 through a wire bonding process using the wires 122 to provide the required current to the light-emitting element 130. The light-emitting element 130 and the semiconductor element 120 are then encapsulated with the transmissive encapsulant 180 to protect the light-emitting element 130 and enhance the luminous efficiency and durability of the light-emitting element 130. Since the light-emitting element 130 generates heat during operation, a good heat dissipation design can prevent overheating and extend the lifespan of the light-emitting element 130.

In one embodiment, the light-emitting element 130 may include an III-V semiconductor material containing Group III and Group V elements, and may be used in lighting, medical, display, communication, sensing, power supply systems, and other fields. When the III-V semiconductor material includes AlGaN, for example, it can emit ultraviolet light with a peak wavelength of 250 nm to 400 nm. When the III-V semiconductor material includes InGaN, for example, it can emit deep blue or blue light with a peak wavelength of 400 nm to 490 nm, or green or yellow light with a peak wavelength of 490 nm to 550 nm. When the III-V semiconductor material includes InGaP or AlGaInP, for example, it can emit yellow, orange, or red light with a peak wavelength of 530 nm to 700 nm. When the III-V semiconductor material includes InGaAs, InGaAsP, AlGaAs, or AlGaInAs, for example, it can emit infrared light with a peak wavelength in the range of 700 nm to 1700 nm. The number and wavelength range of light-emitting elements 130 are not limited and can be adjusted according to actual needs to produce a corresponding light emission spectrum.

In one embodiment, the substrate 110 is, for example, a double-sided copper clad substrate for supporting the semiconductor element 120 and the light-emitting element 130. The manufacturing process of the double-sided copper clad substrate involves, for example, laminating copper foil with prepreg and pressing them together under high temperature and high pressure to form a laminate. The prepreg is an insulating glass fiber cloth or other fiber material that is impregnated with resin, then pretreated and dried to form a sheet. Subsequently, the required vias are drilled in the copper foil substrate. Based on the circuit design, the excess copper foil is etched away to form a circuit. Finally, the copper foil circuit undergoes surface treatment to remove surface oxides and dirt, ensuring a smooth and clean surface thereof.

In one embodiment, a plurality of pads 114 are provided on the substrate 110 for electrically connecting the semiconductor element 120 and the light-emitting element 130. In addition, a plurality of bonding wires 122 are disposed over the substrate 110. The bonding wires 122 are used to electrically connect the semiconductor element 120 to the pads 114 of the substrate 110, to electrically connect the light-emitting element 130 to the pads 114 of the substrate 110, and to electrically connect the semiconductor element 120 to the corresponding light-emitting element 130.

In FIGS. 1 and 2, after the semiconductor element 120 and the light-emitting element 130 complete the wire bonding and packaging process, a reflective cover 140 is placed over the semiconductor element 120. The reflective cover 140 can be a highly reflective optical element that can effectively direct the light beam in the desired direction while maintaining high luminous flux. The reflective cover 140 can be made of a polymer material, such as a silicone resin with reflective fillers. It is typically designed to achieve a reflectivity of 90% or higher at a specific wavelength and can be customized to meet the needs of a specific application. The reflective cover 140 is dispensed in an area covering the semiconductor element 120 and its surroundings, but does not include the area where the light emitting element 130 is located, so as to avoid affecting the light extraction efficiency of the light emitting element 130.

For high-brightness applications of the light-emitting element 130, a high-refractive-index transmissive encapsulant 180, such as high-refractive-index silicone or epoxy resin, can be used as the encapsulation material to enhance heat dissipation and light extraction efficiency. Furthermore, the high-refractive-index transmissive encapsulant 180 can be surface-modified, for example, by modifying a high-refractive-index resin using ozone-ultraviolet (UV) treatment to enhance its surface hardness and reduce adhesion.

Furthermore, to prevent the reflective cover 140 from overflowing during dispensing and affecting the light output of the light-emitting element 130, a first barrier wall 150 is provided between the semiconductor element 120 and the light-emitting element 130. The first barrier wall 150 is used to limit the flow of the reflective cover 140 toward the light-emitting element 130, thereby reducing the probability of overflow. The first barrier wall 150 can also be a polymer material, such as silicone. In some embodiments, reflective particles may also be included to increase reflectivity and reduce light reflection loss within the package structure. In one embodiment, the precursor of the reflective cover 140 may be a resin with a thixotropic coefficient greater than 2. The thixotropic coefficient is also known as the thixotropic index or the thixotropy. The larger the thixotropic coefficient, the better the shape and height of the reflective cover 140 maintain. The height relationship between the reflective cover 140 and the light-emitting element 130 is described below.

As shown in FIG. 2, after the reflective cover 140 is completed, a transmissive encapsulant 180 is then applied to cover the substrate 110, the semiconductor element 120, the light-emitting element 130, the bonding wires 122, the reflective cover 140, and the first barrier wall 150. The transmissive encapsulant 180 is then cured (for example, by baking). In FIG. 2, viewed along the central cross-section of the semiconductor element 120, the outer contour of the reflective cover 140 is curved, and the outer contour of the first barrier wall 150 is also curved. Furthermore, the upper surface 181 of the transmissive encapsulant 180 may be a plane. The outer contour of the reflective cover 140 has an apex 141. This apex 141 is separated from the upper surface 181 of the transmissive encapsulant 180 by a distance G. This distance G is greater than the height H1 of the light-emitting element 130 or another value. This reserved distance G allows light emitted by the light-emitting element 130 to pass through and be reflected or scattered toward regions away from the light-emitting element 130, thereby increasing the amount of light emitted from the regions away from the light-emitting element 130.

In one embodiment, the transmissive encapsulant 180 is molded onto the first surface 111 of the substrate 110 through a mold. The transmissive encapsulant 180 is a highly light-permeable encapsulant used to protect electronic components. Common transmissive encapsulant materials include epoxy resin, silicone, and certain types of polymers, such as ethylene vinyl acetate copolymer (EVA). Epoxy resin has excellent mechanical properties, insulation, corrosion resistance, adhesion, and low shrinkage, while silicone has good optical properties and fluidity and is commonly used in light-emitting diode (LED) packaging.

As shown in FIG. 2, the bonding wire 122 connecting a semiconductor element 120 and the corresponding light-emitting element 130 has an ascending section 122a, a horizontal section 122c, and a descending section 122b. At least one turning angle α is formed between the horizontal section 122c and the descending section 122b, ranging from 110 degrees to 150 degrees. In one embodiment, the position of the ascending section 122a is determined by the ascending height of the bonding wire 122, the position of the horizontal section 122c is determined by the position of the turning portion 123 of the bonding wire 122, and the descending section 122b is determined by the extended length of the bonding wire 122 connected to the pad 114. After the reflective cover 140 covers the semiconductor element 120, portions of the horizontal section 122c and the descending section 122b are exposed outside the reflective cover 140. This increases the resistance to wicking of the uncured reflective resin, preventing it from flowing along the descending section 122b of the bonding wire 122 toward the light-emitting element 130 and affecting the light-emitting effect. Furthermore, experiments have shown that when the reflective cover 140 covers the ascending section 122a and a portion of the horizontal section 122c of the bonding wire 122, the risk of the bonding wire 122 breaking at the bonding point with the semiconductor element 120 is significantly reduced and the product reliability is improved.

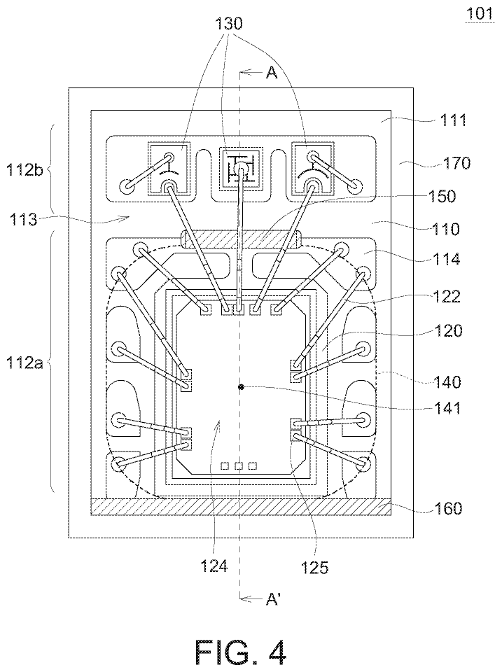

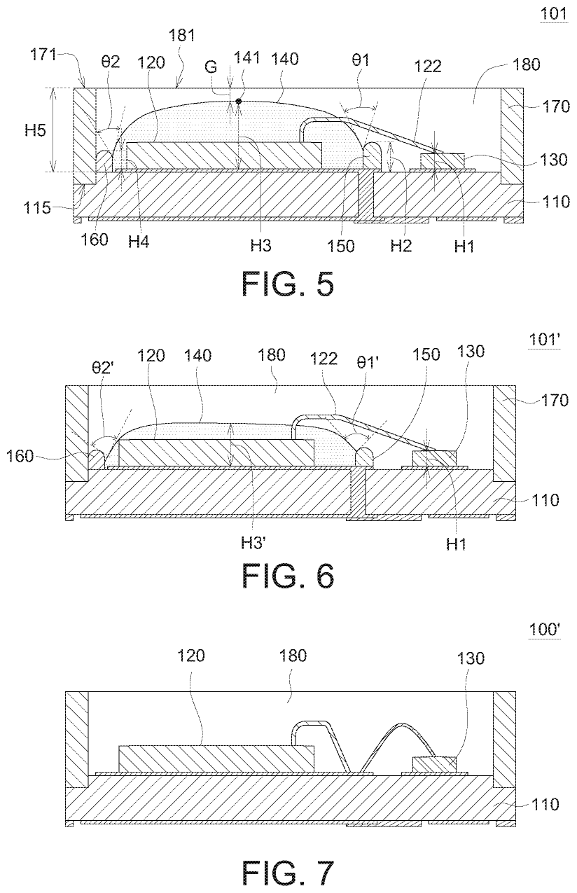

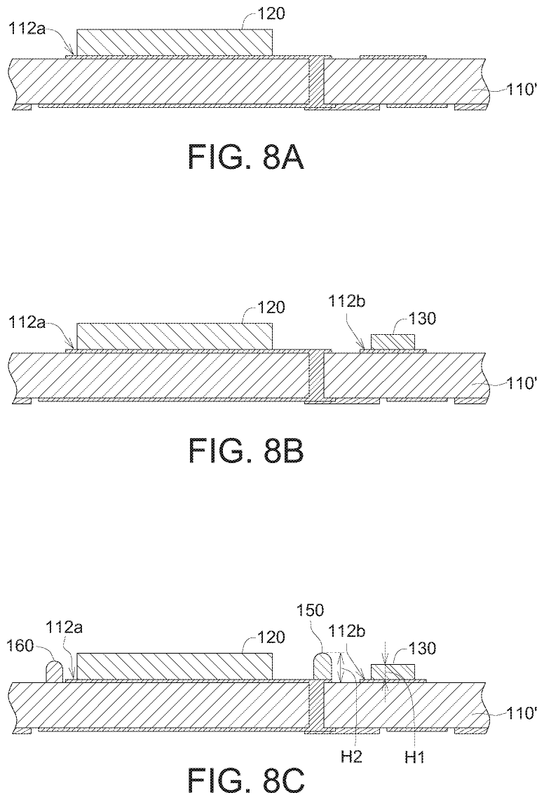

Referring to FIGS. 3 to 5, FIG. 3 illustrates a perspective view of a light-emitting device 101 according to another embodiment of the present invention, FIG. 4 illustrates a plan view of the light-emitting device 101 according to another embodiment of the present invention, and FIG. 5 illustrates a schematic cross-sectional view of the light-emitting device 101 according to another embodiment of the present invention. The light-emitting device 101 includes a substrate 110, a semiconductor element 120, bonding wires 122, at least one light-emitting element 130, a reflective cover 140, a first barrier wall 150, a second barrier wall 160, a third barrier wall 170, and a transmissive encapsulant 180. For the description of the substrate 110, semiconductor element 120, light-emitting element 130, reflective cover 140, first barrier wall 150, and transmissive encapsulant 180, reference is made to the foregoing embodiment and such descriptions are not repeated here. Identical elements are denoted by the same reference numerals.

In the present embodiment, the second barrier wall 160 is disposed on the substrate 110. In another embodiment, the third barrier wall 170 may be included and disposed along the periphery of the substrate 110 to surround the side surfaces of the transmissive encapsulant 180. As shown in FIG. 5, the semiconductor element 120, the light-emitting element 130, the bonding wires 122, the first barrier wall 150, the second barrier wall 160, and the reflective cover 140 are all located in the space surrounded by the third barrier wall 170. As shown in FIG. 5, the second barrier wall 160 is disposed on the substrate 110 and located on the side of the semiconductor element 120 away from the first barrier wall 150 to block the flow of the reflective cover 140 and thus prevent overflow during dispensing. The second barrier wall 160 can be made of a polymer material, such as silicone. The second barrier wall 160 can also contain reflective particles to increase light reflectivity and reduce light reflection loss within the package structure.

In one embodiment, the height H2 of the first barrier wall 150 can be greater than the height H1 of the light-emitting element 130. In another embodiment, the height H4 of the second barrier wall 160 can be greater than the height H1 of the light-emitting element 130. In some embodiments, the heights H2 and H4 of the first and second barrier walls 150 and 160 are, for example, between 9 and 12 mils. The height of the first and/or second barrier walls 150 and 160 being higher than the height of the light-emitting element 130 helps confine the reflective cover 140 to a desired area, preventing it from covering the light-emitting element 130. The height of the first barrier wall 150 also helps control the light pattern. In one embodiment, the bonding wire 122 connecting the semiconductor element 120 and the light-emitting element 130 passes over the top of the first barrier wall 150, and the distance between the first barrier wall 150 and the bonding wire 122 is greater than 1 mil. In other words, the height H2 of the first barrier wall 150 is no greater than the required height of the bonding wires 122 in the subsequent wire bonding process.

Furthermore, the third barrier wall 170 can be made of silicone or a reflective material, effectively reducing light absorption and thereby reducing light reflection loss within the package structure. In FIG. 5, the height H5 of the third barrier wall 170 is higher than the height H3 of the top surface of the reflective cover 140, and the reflective cover 140 can be completely accommodated in the transmissive encapsulant 180.

In one embodiment, the third barrier wall 170 can be formed on a pre-set cutting path 115. The cutting path 115 surrounds the substrate 110 and is typically a pre-designed groove, recess, scribe line, or cut line. The cutting path 115 can be formed by mechanical cutting, laser cutting, or etching. The cutting paths 115 ensure that the third barrier wall 170 can extend into the substrate 110, preventing light leakage from the bottom of the third barrier wall 170 and improving reliability.

The reflective particle concentration in the third barrier wall 170 is a ratio of the filler material to the total volume of the encapsulation material, typically expressed as a volume percentage. The reflective particle concentration affects the properties of the encapsulation material, such as mechanical strength, thermal expansion coefficient, and dielectric properties. Taking epoxy resin or silicone as an example, the reflective particle concentration of the third barrier wall 170 can be greater than that of the first barrier wall 150 to increase the mechanical strength and reflectivity of the third barrier wall 170.

In one embodiment, the upper surface 181 of the transmissive encapsulant 180 is substantially coplanar with the upper surface 171 of the third barrier wall 170. Alternatively, the upper surface 181 of the transmissive encapsulant 180 can be higher than the upper surface 171 of the third barrier wall 170. Referring to FIG. 5, when viewed along the central cross-section of the semiconductor element 120, when the upper surface 181 of the transmissive encapsulant 180 is planar, the outer contour of the reflective cover 140 is slightly lower than the upper surface 181 of the transmissive encapsulant 180, such that the apex 141 of the outer contour of the reflective cover 140 is separated from the upper surface 181 of the transmissive encapsulant 180 by a distance G. This distance G is greater than the height H of the light-emitting element 130 or another value. This reserved distance G allows the light emitted by the light-emitting element 130 to pass through and be reflected or scattered to regions far away from the light-emitting element 130, thereby increasing the amount of light emitted from the regions far away from the light-emitting element 130.

In addition, the transmissive encapsulant 180 may have light-diffusing particles or phosphors to achieve different optical effects. Light-diffusing particles can evenly distribute light, while phosphors can change the color of light and enhance light intensity. In one embodiment, light-diffusing particles, such as silicon dioxide (SiO₂) or aluminum oxide (Al₂O₃), are added to the encapsulation material. Light-diffusing particles can make the light of the light-emitting element 130 softer, providing a more uniform light distribution. In addition, phosphors, such as fluorescent materials doped with rare earth elements, can convert light of a specific wavelength into light of a different wavelength. The principle of phosphors is to absorb excitation light (such as blue light) and then release it as light of a longer wavelength (such as yellow light, green light, red light) to achieve the purpose of light color conversion. For example, a blue light-emitting element can be combined with yellow phosphors to produce white light.

Referring to FIG. 4, the length of the second barrier wall 160 may be greater than or equal to the length of the first barrier wall 150. In one embodiment, the first barrier wall 150 is located on a side of the semiconductor element 120 adjacent to the light-emitting element 130 and does not contact the light-emitting element 130. The space where the first barrier wall 150 is located is narrow, thus preventing the formation of a longer barrier wall. In contrast, the second barrier wall 160 is located on a side away from the light-emitting element 130. The space where the second barrier wall 160 is located is larger, thus allowing the formation of a longer barrier wall.

Furthermore, as shown in FIG. 4, the top surface of the semiconductor element 120 has a plurality of bonding pads 125. The bonding wires 122 may be secured to each of the bonding pads 125 using bonding techniques to establish electrical connections. The bonding pads 125 are distributed around the top surface of the semiconductor element 120. The semiconductor element 120 has a pad free region 124 in the center, and the apex 141 of the outer contour of reflective cover 140 corresponds to the top of pad free region 124. This is because the dispensing needle dispenses the resin from above pad free region 124, allowing the precursor of the reflective cover 140 to flow outward from pad free region 124. This results in a high thixotropic coefficient for the precursor, maintaining its dome shape. Furthermore, apex 141 is located approximately in the center of semiconductor element 120. In other words, if the dispensing needle does not dispense glue above the pad free region 124, the needle may strike the bond wires 122, causing product failure.

Referring to FIG. 5, the height H3 of the reflective cover 140 is 1.5 times, 2 times, or 2.5 times the height H1 of the light-emitting element 130. This allows for more complete reflection of the light emitted by the light-emitting element 130.

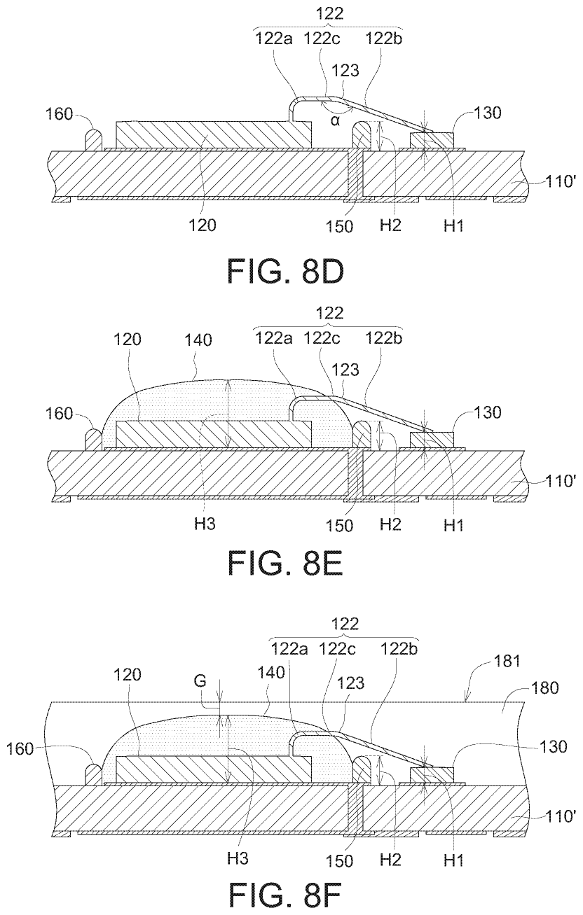

Referring to FIG. 5 and FIG. 6, FIG. 6 illustrates a schematic diagram of a light-emitting device 101′ according to another embodiment. The light-emitting device 101′ of this embodiment differs from the light-emitting device 101 of the aforementioned embodiment in terms of the height of the reflective cover 140, the angle at which the reflective cover 140 intersects with the first barrier wall 150, and the angle at which the reflective cover 140 intersects with the second barrier wall 160. In FIG. 5, the height H3 of the reflective cover 140 is approximately 1.5 to 2 times the height H1 of the light-emitting element 130. In FIG. 6, the height H3′ of the reflective cover 140 is approximately 1.5 times the height H1 of the light-emitting element 130.

As shown in FIG. 5, when viewed along the central cross section of the semiconductor element 120, the first barrier wall 150 contacts the reflective cover 140 and forms an angle θ1 relative to the reflective cover 140. The angle θ1 is less than or equal to 100 degrees, for example, 60 to 90 degrees. The second barrier wall 160 contacts the reflective cover 140 and forms an angle θ2 relative to the reflective cover 140. The angle θ2 is less than or equal to 100 degrees, for example, 60 to 90 degrees.

As shown in FIG. 6, when the height H3′ of the reflective cover 140 decreases, viewed along the central cross section of the semiconductor element 120, the first barrier wall 150 forms an angle θ1′ relative to the reflective cover 140. The angle θ1′ is greater than 100 degrees, for example, 110 to 140 degrees. The second barrier wall 160 forms an angle θ2′ relative to the reflective cover 140. The angle θ2′ is greater than 100 degrees, for example, 110 to 140 degrees.

Referring to FIGS. 5 to 7, FIG. 7 shows a schematic diagram of a light-emitting device 100′ for comparative example. The differences between the light-emitting device 100′ and the light-emitting devices 101 and 101′ of the aforementioned embodiments are described in Table 1. The light-emitting device 100′ in comparative example does not have the reflective cover 140, the first barrier wall 150, and the second barrier wall 160. Compared with the light-emitting devices 101 and 101′ of the aforementioned embodiments, the brightness and light uniformity are poor.

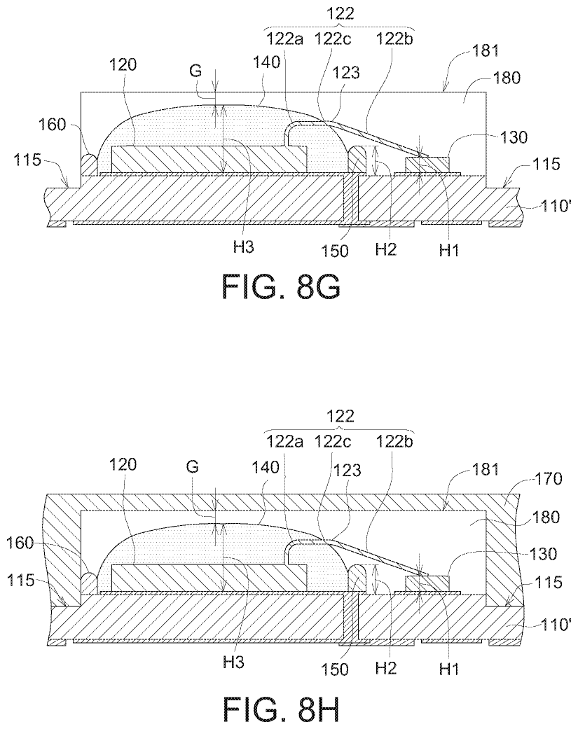

TABLE 1

| | Comparative | | |
|---|---|---|---|
| | Example | Embodiment | Embodiment |
| FIG. No. | FIG. 7 | FIG. 6 | FIG. 5 |
| Brightness | 1600.6(100%) | 2014.2(125.9%) | 2200.8(137.5%) |
| (percentage) | | Brightness increased | Brightness |
| mcd | | | increased |
| Light | Poor | Good | Better |
| uniformity | | | |
| Description | | Overall brightness | Overall brightness |
| | | increased by 25.9% | increased by 37.5% |

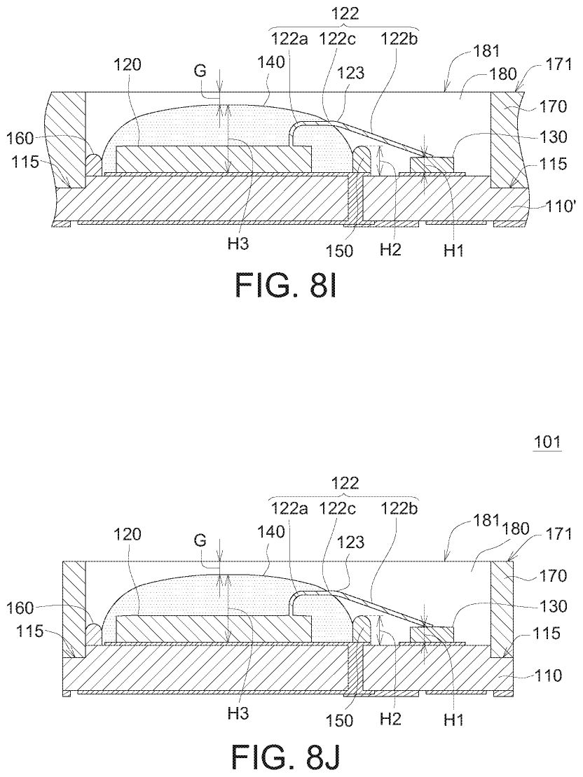

Referring to FIGS. 8A to 8J, cross-sectional schematic diagrams of a method for manufacturing a light-emitting device 101 according to an embodiment of the present invention are illustrated. First, in FIG. 8A, a substrate strip 110′ for packaging is provided, such as a double-sided copper foil substrate. A semiconductor element 120 is disposed in the first chip bonding area 112a of the substrate strip 110′. Next, in FIG. 8B, a light-emitting element 130 is disposed in the second chip bonding area 112b of the substrate strip 110′. In FIG. 8C, a first barrier wall 150 is disposed between the semiconductor element 120 and the light-emitting element 130 by dispensing glue and baking, and a second barrier wall 160 is disposed on the side of the semiconductor element 120 away from the light-emitting element 130. The heights H2 and H4 of the first barrier wall 150 and the second barrier wall 160 are greater than the height H1 of the light-emitting element 130, but the height H2 of the first barrier wall 150 is not greater than the required height of the bonding wire 122 in the subsequent wire bonding process.

Next, in FIG. 8D, a plurality of bonding wires 122 is formed on the substrate strip 110′ using a wire bonding machine. The bonding wires 122 are used to electrically connect the semiconductor element 120 and the pads 114 of the substrate 110 (not shown), to electrically connect the light-emitting element 130 and the pads 114 of the substrate 110 (not shown), and to electrically connect the semiconductor element 120 and the corresponding light-emitting element 130. The bonding wires 122 electrically connecting the semiconductor element 120 and the corresponding light-emitting element 130 can pass across the top of the first barrier wall 150, and the distance between the first barrier wall 150 and the bonding wires 122 can be greater than 1 mil.

In FIG. 8E, a precursor for the reflective cover 140 is dispensed onto the substrate strip 110′ and then thermally cured to form a solid reflective cover 140. The area where the reflective cover 140 is dispensed covers the semiconductor element 120 and its surroundings, but does not include the area where the light-emitting element 130 is located. To prevent overflow of the reflective cover 140 during dispensing, a first barrier wall 150 is provided between the semiconductor element 120 and the light-emitting element 130. Furthermore, the turning portion 123 of the bonding wire 122 is located outside the reflective cover 140. In other words, the horizontal section 122c of the bonding wire 122 is partially exposed outside the reflective cover 140, increasing the resistance to wicking of the uncured reflective adhesive and preventing it from reaching the descending section 122b of the bonding wire 122. This, in turn, alleviates the problem of the reflective adhesive flowing along the descending section 122b of the bonding wire 122 toward the light-emitting element 130.

In FIG. 8F, a transmissive encapsulating material is fluid and dispensed by a mold to completely cover the first surface of the substrate strip 110′. The transmissive encapsulating material is then thermally cured to form a solid-state transmissive encapsulant 180. When the upper surface 181 of the transmissive encapsulant 180 is planar, the upper surface 181 of the transmissive encapsulant 180 is higher than the outer contour of the reflective cover 140, such that the apex of the outer contour of the reflective cover 140 is separated from the upper surface 181 of the transmissive encapsulant 180 by a distance G.

In FIG. 8G, the transmissive encapsulant 180 and the substrate strip 110′ are pre-cut to form a cutting path 115 surrounding the encapsulation unit. Next, in FIG. 8H, a precursor of the third barrier wall 170 is dispensed into substrate strip 110′ by a dispensing process to fully cover the transmissive encapsulant 180, and then thermally cured to form a solid-state third barrier wall 170. The third barrier wall 170 can be formed on the pre-defined cutting path 115 to surround the side of the transmissive encapsulant 180. In FIG. 8I, the remaining material of the third barrier wall 170 covering the transmissive encapsulant 180 is removed by a chemical mechanical polishing process to expose the upper surface 181 of the transmissive encapsulant 180 and the upper surface 171 of the third barrier wall 170.

In FIG. 8J, a cutting machine is used to separate the substrate strip 110′ along the cutting paths 115 of the substrate strip 110′ to form independent light emitting devices 101.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light-emitting device, comprising:
a substrate having a first surface, the first surface having a first chip bonding area and a second chip bonding area;
a semiconductor element disposed on the first chip bonding area;
at least one light-emitting element disposed on the second chip bonding area;
a reflective cover covering the semiconductor element;
a first barrier wall disposed between the semiconductor element and the light-emitting element; and
at least one bonding wire electrically connecting the semiconductor element and the light-emitting element;
wherein a height of the reflective cover is greater than a height of the first barrier wall, and the height of the first barrier wall is greater than a height of the light-emitting element.

2. The light-emitting device of claim 1, wherein, as viewed along a central cross-section of the semiconductor element, the first barrier wall contacts the reflective cover and forms an angle relative to the reflective cover, and the angle is less than or equal to 100 degrees.

3. The light-emitting device of claim 1, wherein the height of the reflective cover is 1.5 to 2.5 times the height of the light-emitting element.

4. The light-emitting device of claim 1, further comprising a second barrier wall disposed on the substrate and located on a side of the semiconductor element away from the first barrier wall.

5. The light-emitting device of claim 4, wherein the height of the reflective cover is greater than a height of the second barrier wall.

6. The light-emitting device of claim 4, wherein, as viewed along a central cross-section of the semiconductor element, the second barrier wall contacts the reflective cover and forms an angle relative to the reflective cover, the angle is less than or equal to 100 degrees.

7. The light-emitting device of claim 1, wherein the bonding wire has an ascending section, a horizontal section, and a descending section, with portions of the horizontal section and the descending section exposed outside the reflective cover.

8. The light-emitting device of claim 7, wherein the horizontal section and the descending section have at least one turning angle therebetween, and the turning angle is greater than 110 degrees.

9. The light-emitting device of claim 1, wherein the first barrier wall and the reflective cover do not contact the light-emitting element.

10. The light-emitting device of claim 1, wherein an upper surface of the semiconductor element has a plurality of bonding pads, the bonding pads are distributed around the upper surface of the semiconductor element, a pad free region is provided in a middle of the semiconductor element, and an outer contour of the reflective cover has an apex corresponding to the pad free region.

11. The light-emitting device of claim 1, wherein, as viewed along a central cross-section of the semiconductor element, an outer contour of the reflective cover is curved, and an outer contour of the first barrier wall is curved.

12. The light-emitting device of claim 11, wherein a curvature of the outer contour of the reflective cover is smaller than a curvature of the outer contour of the first barrier wall.

13. The light-emitting device of claim 1, further comprising a second barrier wall, the second blocking wall being disposed on the substrate and located on a side of the semiconductor element away from the first barrier wall.

14. The light-emitting device of claim 13, wherein a height of the second blocking wall is greater than the height of the light-emitting element.

15. The light-emitting device of claim 13, wherein a length of the second barrier wall is greater than a length of the first barrier wall.

16. The light-emitting device of claim 1, further comprising a transmissive encapsulant disposed on the first surface, wherein the transmissive encapsulant covers the semiconductor element, the light-emitting element, the bonding wire, the first barrier wall, and the reflective cover.

17. The light-emitting device of claim 16, further comprising a third barrier wall disposed along a periphery of the substrate, wherein the third barrier wall surrounds side surfaces of the transmissive encapsulant.

18. The light-emitting device of claim 16, wherein, as viewed along a central cross-section of the semiconductor element, an outer contour of the reflective cover has an apex, and the apex is spaced apart from an upper surface of the transmissive encapsulant by a distance.

19. The light-emitting device of claim 18, wherein the distance is greater than the height of the light-emitting element.

20. The light-emitting device of claim 17, wherein a concentration of reflective particles in the third barrier wall is greater than a concentration of reflective particles in the first barrier wall.
